(19) United States
(12) Patent Application Publication
(10) Pub. No.: US 2026/0029450 A1
(43) Pub. Date: Jan. 29, 2026

(54) EMC Countermeasure Presentation System and EMC Countermeasure Presentation Method

(71) Applicant: Hitachi, Ltd., Tokyo (JP)

(72) Inventor: Kiyoto MATSUSHIMA, Tokyo (JP)

(21) Appl. No.: 19/265,173

(22) Filed: Jul. 10, 2025

(30) Foreign Application Priority Data
Jul. 23, 2024 (JP) 2024-117856

(51) Int. Cl. G01R 29/26; G01R 29/08; G01R 31/00; G06N 3/0464

(52) U.S. Cl. CPC G01R 29/26; G01R 29/0814; G01R 31/001; G06N 3/0464

(57) ABSTRACT

An EMC countermeasure presentation system includes: a necessary reduction amount extraction unit that converts measurement noise frequency data of an evaluation target device with a predetermined threshold value as a reference and generates necessary reduction amount frequency data; a reduction countermeasure extraction unit that extracts noise countermeasure reduction amount frequency data close in distance from countermeasure reduction amount learning data obtained by learning noise countermeasure reduction amount frequency data in a noise reduction countermeasure database based on the necessary reduction amount frequency data generated by the necessary reduction amount extraction unit; a similar configuration extraction unit that extracts device configuration data close in distance from configuration learning data obtained by learning a graph model representing a device configuration when the noise countermeasure reduction amount frequency data in the noise reduction countermeasure database is acquired, based on the device configuration data at time of noise measurement of the evaluation target device; and a countermeasure estimation unit that estimates a recommended countermeasure content having a high similarity in a device connection configuration and an expected effect of reducing excessive noise, from data obtained from the reduction countermeasure extraction unit and the similar configuration extraction unit.

### CLAIM OF PRIORITY

The present application claims priority from Japanese Patent application serial no. 2024-117856, filed on Jul. 23, 2024, the content of which is hereby incorporated by reference into this application.

### BACKGROUND OF THE INVENTION

### 1. Field of the Invention

The present invention relates to a configuration and a method of an EMC countermeasure presentation system that proposes a countermeasure for reducing electromagnetic noise to a user.

### 2. Description of the Related Art

Electromagnetic waves (emission) emitted from an electronic device may cause electromagnetic wave interference that interferes with the function of another device. Therefore, in order to normally operate the electronic device without an occurrence of an erroneous function or failure, countermeasures against excessive electromagnetic noise, that is, electromagnetic compatibility (EMC) countermeasures are required. Most of the countermeasure contents are based on experience and knowledge of workers and engineers.

As the related art of the present technical field, for example, there is a technique such as JP 5-334457 A. JP 5-334457 A relates to a noise analysis device and discloses that when measurement data of noise measured from a device to be treated is larger than a standard value, a database is searched to select a countermeasure component (countermeasure method) corresponding to the noise, and to cause the measurement data of noise to fall within the standard value, thereby obtaining an optimal noise countermeasure in a short time.

WO 2022/168332 A discloses that a narrowband spectrum waveform of a single noise cause component is learned, and noise cause component data is specified and presented from a component data list based on inference and classification using, as an input, a spectrum waveform of an excessive noise unit in a device noise measurement result, thereby reducing a burden of noise cause specification work.

### SUMMARY OF THE INVENTION

If cases of similar past emission countermeasures in other fields and other models can be extracted and utilized as electromagnetic noise reduction countermeasures, it leads to suppression of examination time and cost of countermeasure contents.

However, with the conventional technique, it is difficult to efficiently extract and utilize cases of emission countermeasures in other fields and other models, and there is a possibility that the examination time is wastefully consumed even in a case of an event experienced in the past.

In JP 5-334457 A described above, only a predetermined position and a reduction effect of determined circuit configuration candidates can be examined, and the effect of the countermeasure is limited.

In WO 2022/168332 A described above, it is necessary to accumulate data in a single component that causes noise, and it is also possible to associate the noise causing component with a countermeasure, but there is only association means in a personal manner, and the accuracy of the reduction effect is low, and it is very difficult to take other cases.

Therefore, an object of the present invention is to provide an EMC countermeasure presentation system and an EMC countermeasure presentation method capable of efficiently extracting and presenting an emission countermeasure case in another field and another model having high similarity (countermeasure effectiveness) in consideration of a device configuration of an electronic device.

In order to solve the above problems, the present invention includes: a necessary reduction amount extraction unit that converts measurement noise frequency data of an evaluation target device with a predetermined threshold value as a reference and generates necessary reduction amount frequency data, a reduction countermeasure extraction unit that extracts noise countermeasure reduction amount frequency data close in distance from countermeasure reduction amount learning data obtained by learning noise countermeasure reduction amount frequency data in a noise reduction countermeasure database based on the necessary reduction amount frequency data generated by the necessary reduction amount extraction unit, a similar configuration extraction unit that extracts device configuration data close in distance from configuration learning data obtained by learning a graph model representing a device configuration when the noise countermeasure reduction amount frequency data in the noise reduction countermeasure database is acquired, based on the device configuration data at time of noise measurement of the evaluation target device, and a countermeasure estimation unit that estimates a recommended countermeasure content having a high similarity in a device connection configuration and an expected effect of reducing excessive noise, from data obtained from the reduction countermeasure extraction unit and the similar configuration extraction unit.

In addition, the present invention includes: (a) converting measurement noise frequency data of an evaluation target device with a predetermined threshold value as a reference and generates necessary reduction amount frequency data; (b) extracting noise countermeasure reduction amount frequency data close in distance from countermeasure reduction amount learning data obtained by learning noise countermeasure reduction amount frequency data in a noise reduction countermeasure database based on the necessary reduction amount frequency data generated in (a); (c) extracting device configuration data close in distance from configuration learning data obtained by learning a graph model representing a device configuration when the noise countermeasure reduction amount frequency data in the noise reduction countermeasure database is acquired, based on the device configuration data at time of noise measurement of the evaluation target device; and (d) estimating a recommended countermeasure content having a high similarity in a device connection configuration and an expected effect of reducing excessive noise, from data obtained from (b) and (c).

According to the present invention, it is possible to realize an EMC countermeasure presentation system and an EMC countermeasure presentation method capable of efficiently extracting and presenting an emission countermeasure case in another field and another model having high similarity (countermeasure effectiveness) in consideration of a device configuration of an electronic device.

As a result, it is possible to contribute to reduction of a countermeasure time and cost of the electromagnetic noise reduction countermeasure.

Objects, configurations, and advantageous effects other than those described above will be clarified by the descriptions of the following embodiments.

### BRIEF DESCRIPTION OF THE DRAWINGS

FIG. 1 is a diagram illustrating a schematic configuration of an EMC countermeasure presentation system according to a first embodiment of the present invention;

FIG. 2 is a diagram schematically illustrating a function of a necessary reduction amount extraction unit in FIG. 1;

FIG. 3 is a diagram illustrating a presentation example of a presentation unit in FIG. 1;

FIG. 4 is a diagram schematically illustrating a function of a reduction countermeasure extraction unit in FIG. 1;

FIG. 5 is a diagram schematically illustrating an electromagnetic connection model;

FIG. 6 is a diagram schematically illustrating a model registration process in structure learning data generation;

FIG. 7 is a diagram schematically illustrating the model registration process in similar structure estimation;

FIG. 8 is a diagram illustrating an example of a search result;

FIG. 9 is a diagram schematically illustrating a function of a countermeasure estimation unit in FIG. 1;

FIG. 10 is a flowchart illustrating a data construction process in a noise reduction countermeasure database in FIG. 1;

FIG. 11 is a diagram illustrating an example of measurement noise data in FIG. 1;

FIG. 12 is a flowchart illustrating processing in a data commonization processing unit in FIG. 10;

FIG. 13 is a diagram schematically illustrating a function of a difference calculation unit in FIG. 10;

FIG. 14 is a diagram schematically illustrating a function of a countermeasure difference detection unit in FIG. 10;

FIG. 15 is a diagram schematically illustrating a function of a data table generation unit in FIG. 10; and

FIG. 16 is a flowchart illustrating an EMC countermeasure presentation method according to the first embodiment of the present invention.

### DESCRIPTION OF THE PREFERRED EMBODIMENTS

Hereinafter, embodiments of the present invention will be described with reference to the drawings. In the drawings, the same components are denoted by the same reference signs, and the detailed description of the repetitive parts will be omitted.

### First Embodiment

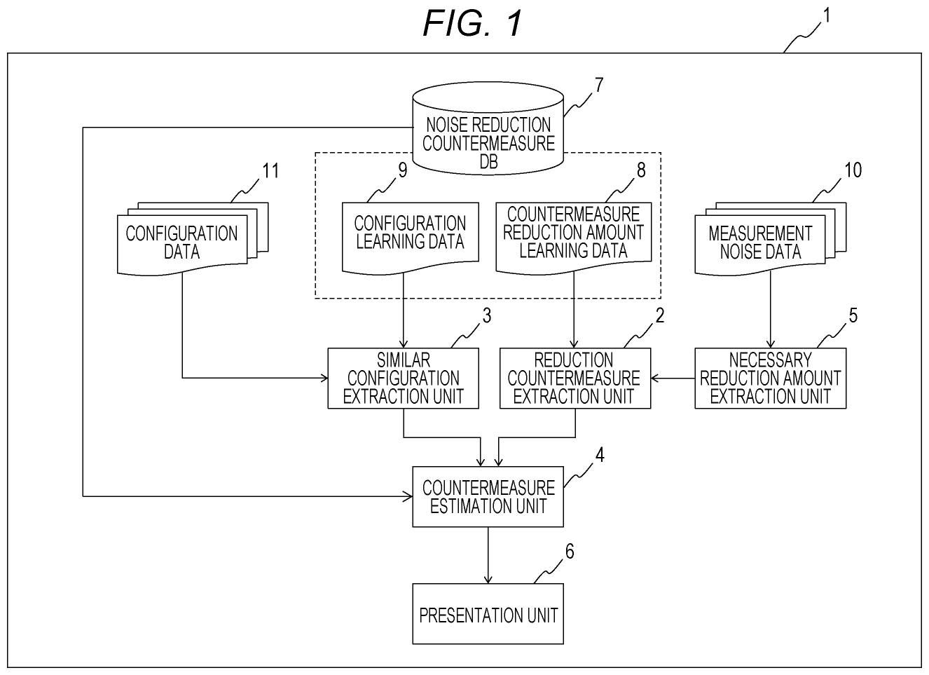

An EMC countermeasure presentation system and an EMC countermeasure presentation method according to a first embodiment of the present invention will be described with reference to FIGS. 1 to 16.

FIG. 1 is a diagram illustrating a schematic configuration of an EMC countermeasure presentation system 1 according to the present embodiment.

As illustrated in FIG. 1, the EMC countermeasure presentation system 1 according to the present embodiment includes, as main components, a reduction countermeasure extraction unit 2, a similar configuration extraction unit 3, a countermeasure estimation unit 4, a necessary reduction amount extraction unit 5, and a presentation unit 6.

Although FIG. 1 illustrates an example in which the EMC countermeasure presentation system 1 is configured to include a noise reduction countermeasure database (DB) 7, the noise reduction countermeasure database (DB) 7 may be installed outside and connected to the EMC countermeasure presentation system 1 by wired communication or wireless communication.

The EMC countermeasure presentation system 1 further includes an input device (not illustrated) that inputs data necessary for processing, for example, measurement noise data 10 such as measurement noise frequency data of an evaluation target device and configuration data 11 of the evaluation target device.

As a specific hardware configuration example of the EMC countermeasure presentation system 1, the reduction countermeasure extraction unit 2, the similar configuration extraction unit 3, the countermeasure estimation unit 4, and the necessary reduction amount extraction unit 5 can be configured by a central processing unit (CPU), the noise reduction countermeasure database (DB) 7 can be configured by a storage device (memory), and the presentation unit 6 and the input device (not illustrated) can be configured by an input/output device (I/O).

The EMC countermeasure presentation system 1 in the present embodiment converts the measurement noise data of the evaluation target device into a necessary noise reduction amount, and presents the user with appropriate countermeasure contents based on comparison with the noise reduction amount in the noise reduction countermeasure database (DB) 7 and similarity of the device configuration.

The necessary reduction amount extraction unit 5 converts the input measurement noise data 10 such as the measurement noise frequency data of the evaluation target device into a difference from a predetermined threshold value (standard value or the like) to generate necessary reduction amount frequency data.

Based on the necessary reduction amount frequency data generated by the necessary reduction amount extraction unit 5, the reduction countermeasure extraction unit 2 extracts noise countermeasure reduction amount frequency data close in distance from countermeasure reduction amount learning data 8 obtained by learning the noise countermeasure reduction amount frequency data in the noise reduction countermeasure database (DB) 7.

Based on the input configuration data 11 of the evaluation target device at the time of noise measurement, the similar configuration extraction unit 3 extracts device configuration data close in distance from configuration learning data 9 obtained by learning a graph model representing a device configuration when the noise countermeasure reduction amount frequency data in the noise reduction countermeasure database (DB) 7 is acquired.

From data obtained from the reduction countermeasure extraction unit 2 and the similar configuration extraction unit 3, the countermeasure estimation unit 4 estimates a recommended countermeasure content that has a high similarity of a device connection configuration and has an expected effect of reducing excessive noise.

The presentation unit 6 presents a user with the recommended countermeasure content estimated by the countermeasure estimation unit 4. Examples of the presentation unit 6 include a display device and a voice output device.

The device structure of the evaluation target device, the specific measure content, and the noise reduction amount are saved in advance in the noise reduction countermeasure database (DB) 7.

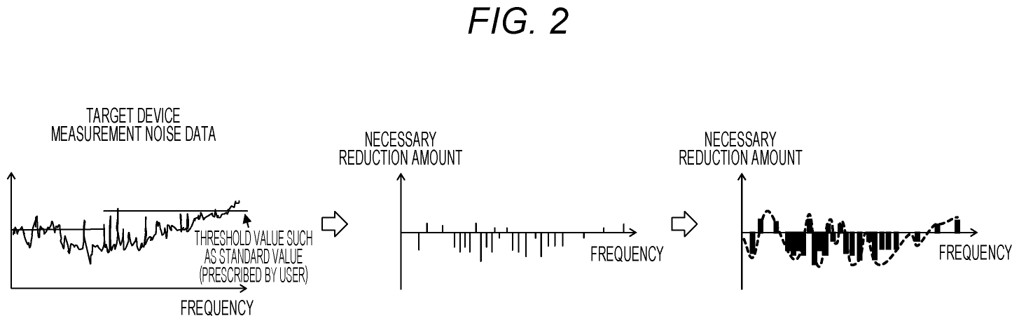

FIG. 2 is a diagram schematically illustrating the function of the necessary reduction amount extraction unit 5 in FIG. 1.

As illustrated in FIG. 2, the necessary reduction amount extraction unit 5 converts the measurement noise data of the evaluation target device into a difference amount from the threshold value prescribed by the user.

At this time, processing of representing an improvement amount with a predetermined frequency step width, interpolating between improvement amount data points, or the like may be added in accordance with the necessary detection accuracy.

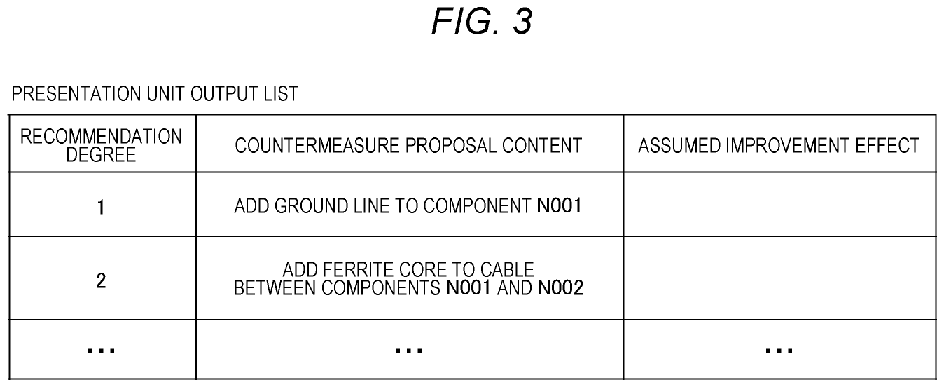

FIG. 3 is a diagram illustrating a presentation example of the presentation unit 6 in FIG. 1.

As illustrated in FIG. 3, the presentation unit 6 presents the user with the estimation result by the countermeasure estimation unit 4 as a presentation unit output list. For example, a countermeasure of adding a ground line to a component N001 is presented as a countermeasure proposal content of Recommendation degree 1. A countermeasure of adding a ferrite core to a cable between components N001 and N002 is presented as a countermeasure proposal content of Recommendation degree 2. The expected reduction amount, the reflected assumed noise data, and the like are displayed as the assumed improvement effect for the countermeasure proposal content.

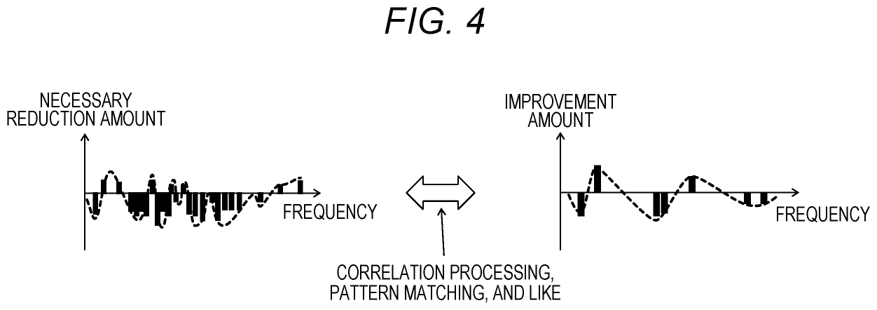

FIG. 4 is a diagram schematically illustrating the function of the reduction countermeasure extraction unit 2 in FIG. 1.

As illustrated in FIG. 4, the reduction countermeasure extraction unit 2 compares the necessary reduction amount converted by the necessary reduction amount extraction unit 5 with the improvement amount data in the noise reduction countermeasure database (DB) 7 by correlation processing, pattern matching, or the like, and extracts (proposes) one or more combination countermeasures.

The similar configuration extraction unit 3 can also extract information of another model and another device in which the similarity of the device configuration of the evaluation target device is viewed, and a close configuration (same device) appears at a higher level. In the similar configuration extraction unit 3, since a graph structure representing the device structure is complicated, it is preferable to adopt a graph convolution neural-network (GCN).

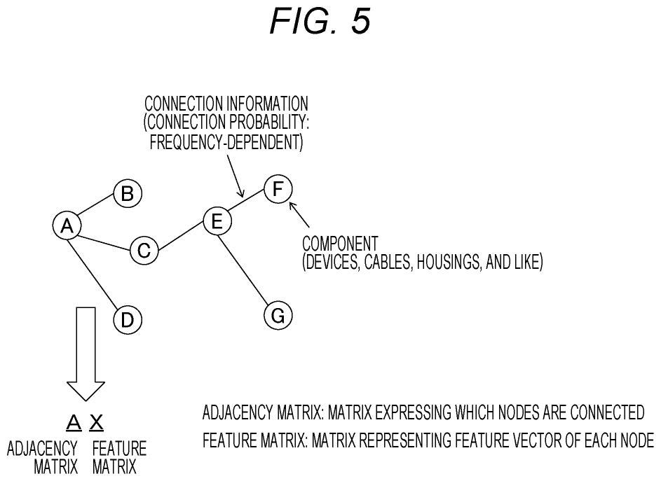

FIG. 5 is a diagram schematically illustrating an electromagnetic connection model.

As illustrated in FIG. 5, the electromagnetic connection model is configured by an image in which components A to G such as a device, a cable, and a housing constituting the evaluation target device are connected with connection information such as a connection probability and frequency dependence. This electromagnetic connection model can be expressed by a combination of the adjacency matrix A and the feature matrix X. The adjacency matrix A is a matrix expressing which nodes are connected, and the feature matrix X is a matrix representing a feature vector of each node.

As an example of a node feature amount, the component attribute is set as a variable indicating a component type at a system level, such as a board, a signal device, a motor, a cable, and a housing. Even at a circuit level such as an element or a wiring, it is sufficient that a connection relationship can be expressed in the same layer. A nested structure with a system-level component may be employed. The detailed component information may include an oscillation frequency and the like in the case of a noise source, and a cable length and the like in the case of a cable.

As an example of an edge feature amount, “1” is given by electrical direct connection, and the connection possibility is weighted by 0 to 1 from past cases, a distance between conductors on CAD, and the like. The parasitic capacitance may be subjected to connection weighting that varies with the frequency, such as “0” in the case of being unconnected at a low frequency and “1” in the case of being connected at a radio frequency.

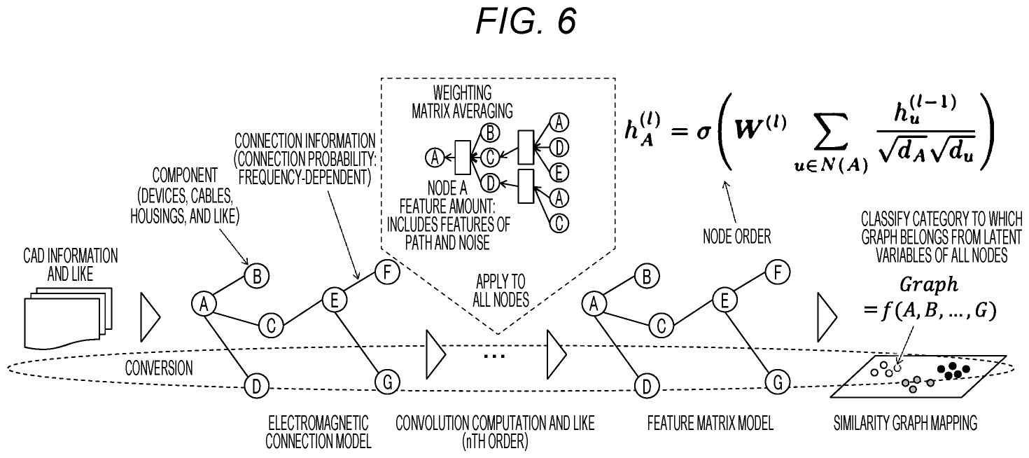

FIG. 6 is a diagram schematically illustrating a model registration process in structure learning data generation.

As illustrated in FIG. 6, in the structure learning data generation, a graph pattern matching model is constructed by applying a graph convolution neural-network (GCN).

First, CAD information and the like are converted to generate an electromagnetic connection model. The electromagnetic connection model is as described above with reference to FIG. 5.

Then, weighting matrix conversion and averaging processing are performed on all nodes by an nth-order convolution computation or the like to generate a feature matrix model. At this time, the node order can be obtained by the expression in FIG. 6. The feature amount of each node is expressed by adding/averaging the feature amounts of the adjacent nodes. That is, the feature amount expresses information regarding how the node is connected. Computation including the feature amount of the edge may be performed.

The category to which the graph belongs is classified from the latent variables of all the nodes, and similar graph mapping is generated.

The feature matrix model and the similarity graph mapping may be supervised learning in which the feature matrix model is set as an explanatory variable, and a classification ID (field) or a countermeasure reduction amount is set as an objective variable.

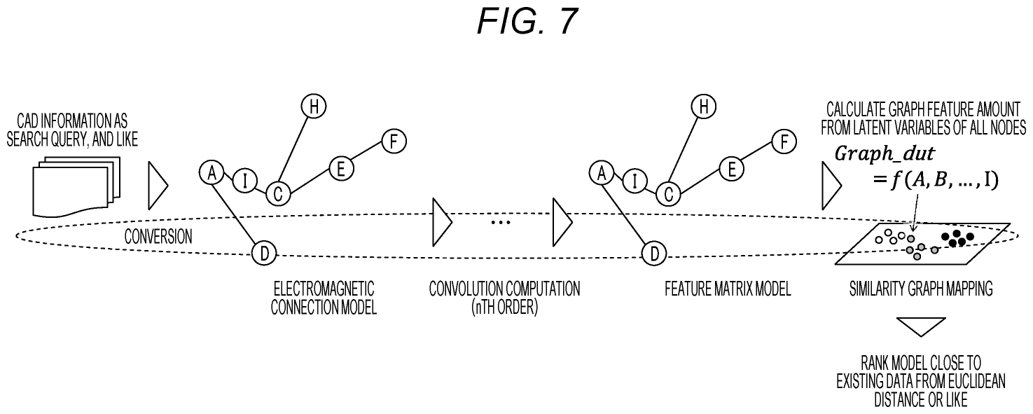

FIG. 7 is a diagram schematically illustrating the model registration process in similar structure estimation.

First, CAD information or the like as a search query is converted to generate the electromagnetic connection model. The electromagnetic connection model is as described above with reference to FIG. 5.

Then, weighting matrix conversion and averaging processing are performed on all nodes by an nth-order convolution computation or the like to generate a feature matrix model. The generation of the feature matrix model is as described above with reference to FIG. 6.

The graph feature amount is calculated from the latent variables of all the nodes, and the similar graph mapping is generated. A close model is ranked from the generated similar graph mapping, the Euclidean distance from the existing data, and the like.

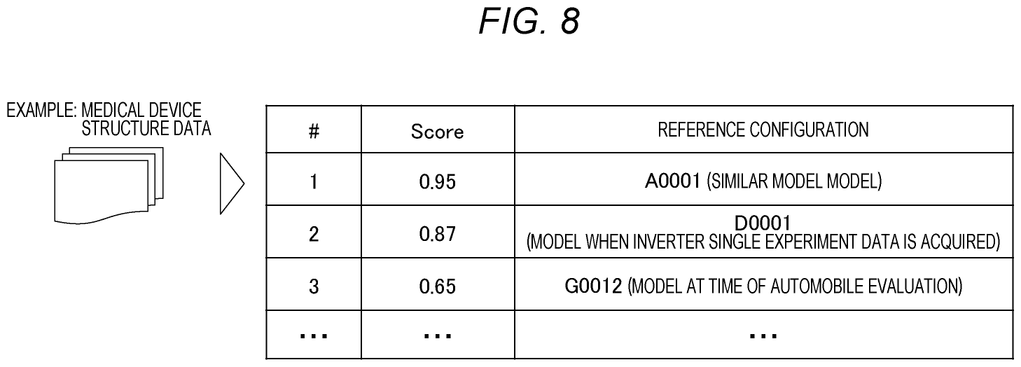

FIG. 8 is a diagram illustrating an example of a search result and illustrates an example in a medical device.

As illustrated in FIG. 8, reference configurations such as a similar model model, an inverter single experiment data acquisition model, and an automobile evaluation model are displayed in order of scores. In the example of FIG. 8, the scores are displayed in descending order. The similar structure data in terms of EMC that cannot be searched by a normal system is extracted.

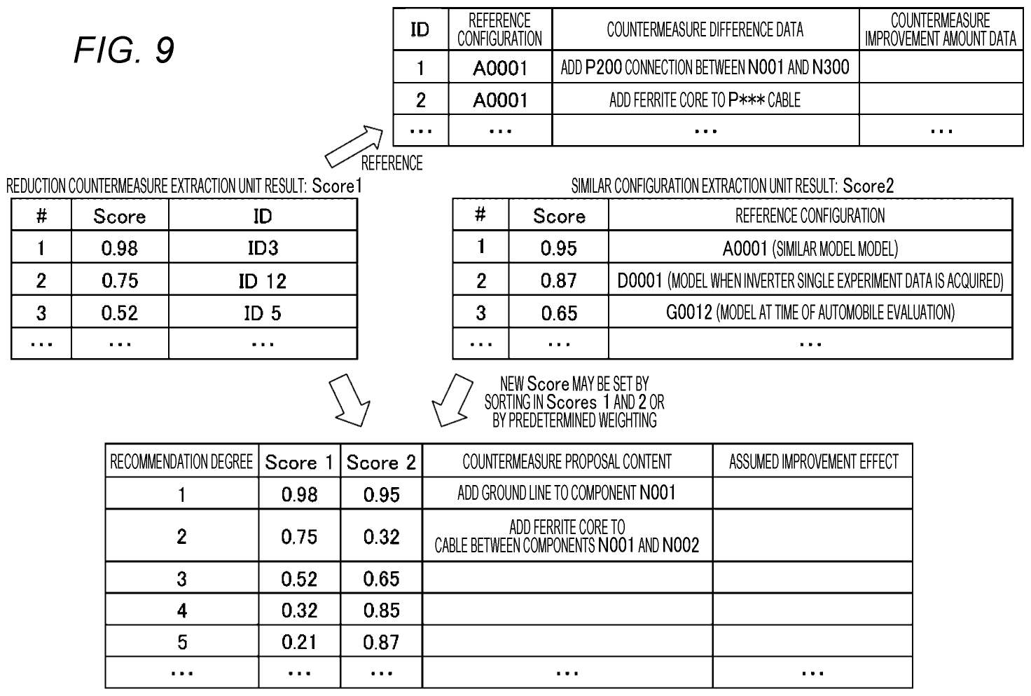

FIG. 9 is a diagram schematically illustrating the function of the countermeasure estimation unit 4 in FIG. 1.

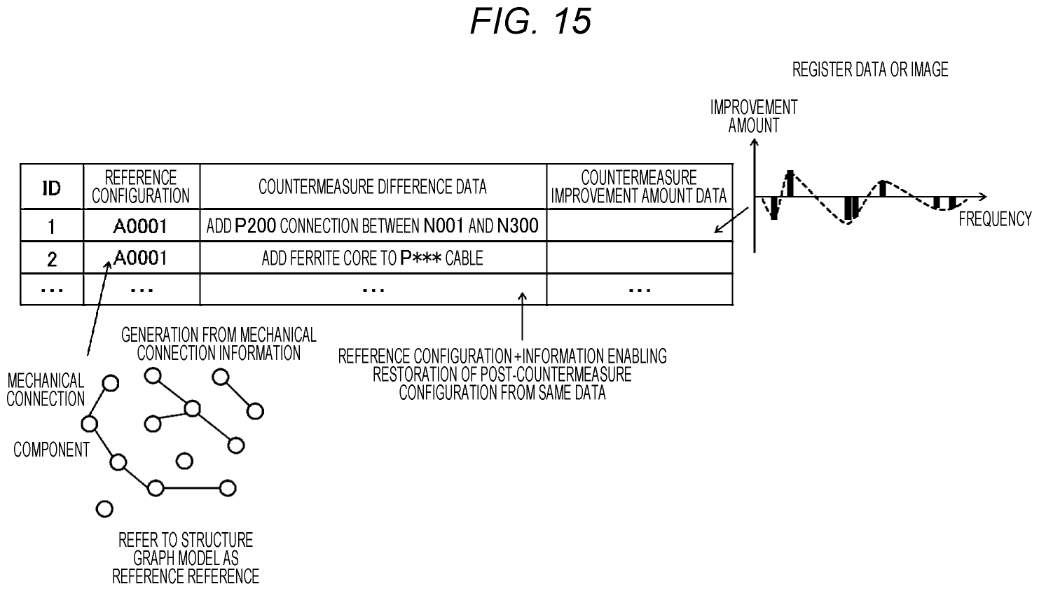

As illustrated in FIG. 9, the countermeasure estimation unit 4 refers to a data table which will be described later with reference to FIG. 15, based on the extraction result in the reduction countermeasure extraction unit 2.

The countermeasure estimation unit 4 estimates a recommended countermeasure content (see FIG. 3) based on the extraction result by the reduction countermeasure extraction unit 2 and the extraction result (see FIG. 8) by the similar configuration extraction unit 3.

If both the result of the reduction countermeasure extraction unit (Score 1) and the result of the similar configuration extraction unit (Score 2) have high scores, a reliable countermeasure effect can be obtained.

Since there is a possibility that the configuration is different or the noise frequency characteristic is changed, other products and component single body test data can also be included in the list.

A new score may be set by sorting with Score 1 and Score 2 or by predetermined weighting.

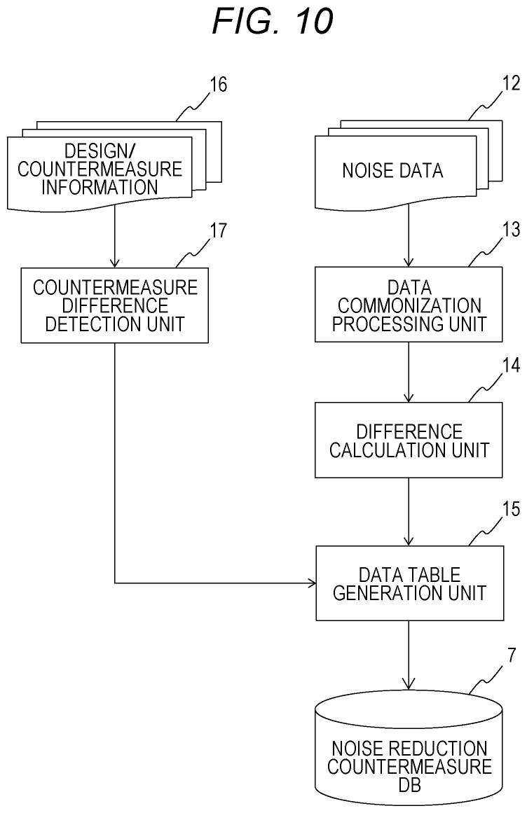

FIG. 10 is a flowchart illustrating a data construction process in the noise reduction countermeasure database 7 in FIG. 1.

As illustrated in FIG. 10, in the data construction process in the noise reduction countermeasure database 7, the noise data of the device configuration as the reference is compared with the same data after the application of the countermeasure (after the change in the device configuration), and the relative difference between the configuration difference and the noise reduction amount is evaluated.

First, when the noise data 12 under different measurement conditions such as the voltage, the current, the power, the electric field, and the magnetic field is input, a data commonization processing unit 13 converts the time-series data and the spectrogram data of the measurement noise frequency data into two-dimensional frequency axis data. As a result, both the time-series data and the spectrogram data of the measurement noise frequency data can be processed as two-dimensional frequency axis data.

Then, a difference calculation unit 14 performs conversion into a difference amount from a threshold value prescribed by the user. The comparison data is saved as an improvement amount that does not depend on the measurement conditions.

When design/countermeasure information 16 of the evaluation target device is input, a countermeasure difference detection unit 17 eliminates ambiguity of the change content.

Based on the data generated by the difference calculation unit 14 and the data generated by the countermeasure difference detection unit 17, a data table generation unit 15 generates a data table and stores the data table in the noise reduction countermeasure database 7. The data table will be described later with reference to FIG. 15.

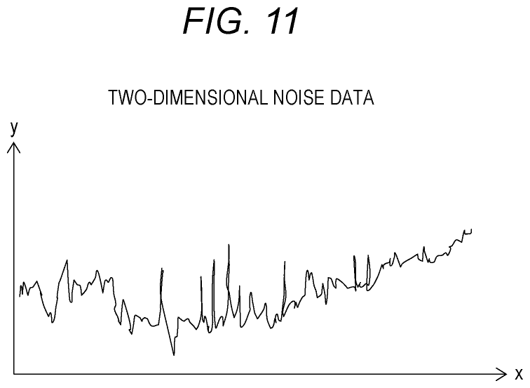

FIG. 11 is a diagram illustrating an example of the measurement noise data 10 in FIG. 1.

The format of “noise data” varies depending on measurement conditions (observation/data, setting). For example, the noise data prescribed by the standard (measured with an antenna 3 m away from a test target) often has few test conditions, and the amount of data is often insufficient as a database for achieving the reduction effect. Therefore, many of pieces of the noise reduction effect data are not unique in measurement, measurement location, and format in trial and error examinations at the laboratory level/on site countermeasures, and it is difficult to compare the result graphs with each other.

As the noise data, for example, three-dimensional noise data such as a spectrogram is also conceivable in addition to the two-dimensional noise data as illustrated in FIG. 11.

In the EMC countermeasure presentation system 1 in the present embodiment, the noise data of the device configuration as the reference is compared with the same data after application of the countermeasure (after the change in device configuration), and the relative difference between the configuration difference and the noise reduction amount is evaluated.

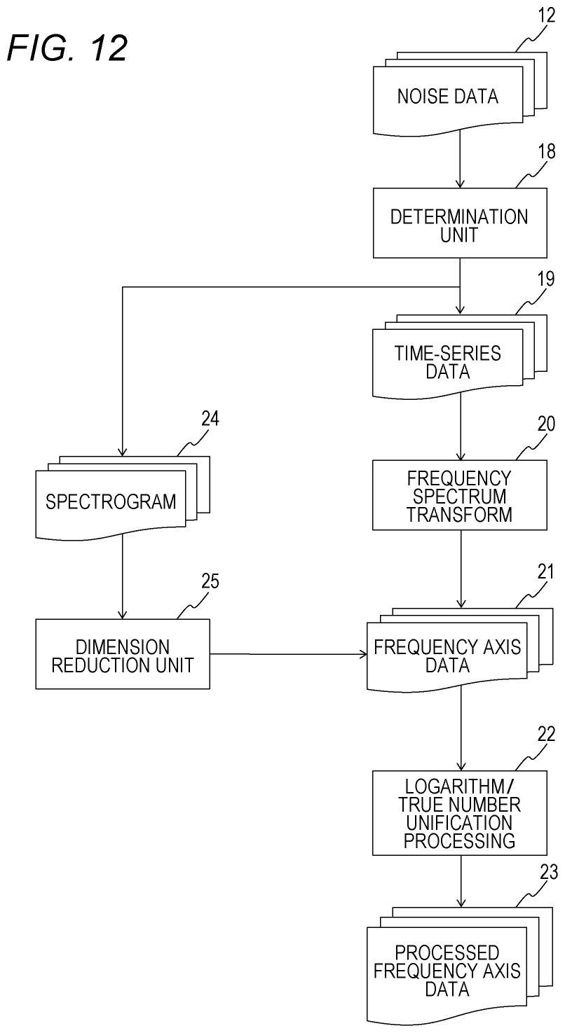

FIG. 12 is a flowchart illustrating processing in the data commonization processing unit 13 in FIG. 10.

As illustrated in FIG. 12, the data commonization processing unit 13 performs processing of converting the format of the input data into frequency axis data.

First, when the noise data 12 is input, a determination unit 18 determines whether the input noise data 12 is time-series data 19 or a spectrogram 24.

The data determined to be the time-series data 19 is subjected to Fourier transform in frequency spectrum transform 20.

The data determined to be the spectrogram 24 is two-dimensionalized by Peak hold, Quasi-peak, Average processing, or the like in a dimension reduction unit 25.

The frequency axis data 21 is generated based on the data Fourier-transformed by the frequency spectrum transform 20 and the data two-dimensionalized by the dimension reduction unit 25.

The vertical axis and the horizontal axis of the frequency axis data 21 are unified in a predetermined scale by logarithm/true number unification processing 22, and are generated as the processed frequency axis data 23. In the processed frequency axis data 23, power [W], voltage [V], current [I], electric field [V/m], and magnetic field [A/m] are mixed.

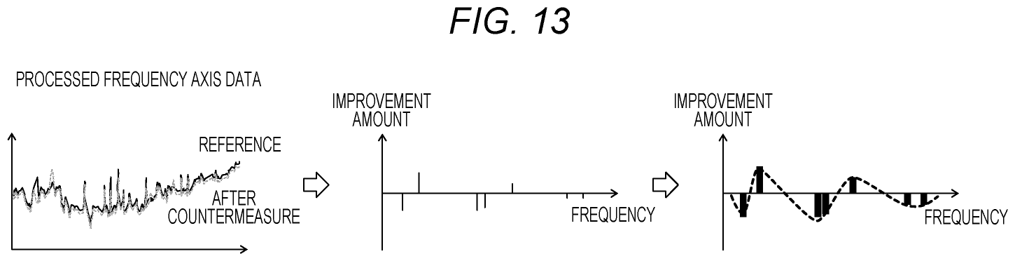

FIG. 13 is a diagram schematically illustrating the function of the difference calculation unit 14 in FIG. 10.

As illustrated in FIG. 13, the difference calculation unit 14 performs processing of calculating a difference from the measurement result in the reference configuration (required to be designated) and performing conversion into a countermeasure improvement amount. The comparison data is saved as the improvement amount that does not depend on the measurement conditions.

At this time, processing of representing an improvement amount with a predetermined frequency step width, interpolating between improvement amount data points, or the like may be added in accordance with the necessary detection accuracy.

The reference configuration may be designated by the user, or may be automatically determined from configuration data, for example, based on a simpler configuration.

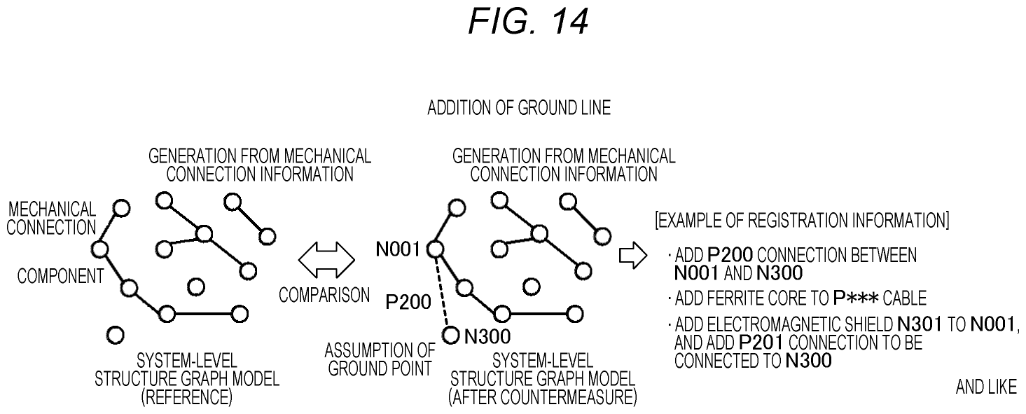

FIG. 14 is a diagram schematically illustrating the function of the countermeasure difference detection unit 17 in FIG. 10.

As illustrated in FIG. 14, the countermeasure difference detection unit 17 performs processing of detecting a difference in structure before and after a countermeasure, from data (graph model or the like) indicating an electrical connection configuration of the evaluation target device. Then, ambiguity of the change content is eliminated.

As registration information, the notation accuracy may be adjusted according to the level of the graph model, and notation at the substrate level is also possible.

FIG. 15 is a diagram schematically illustrating the function of the data table generation unit 15 in FIG. 10.

As illustrated in FIG. 15, the data table generation unit 15 generates and registers the data table by matching the countermeasure content with the noise reduction amount by the countermeasure.

The data is registered in the reference configuration with reference to the structure graph model as the reference. In the countermeasure difference data, the reference configuration and information that enables restoration of the post-countermeasure configuration from the same data are registered. In the countermeasure improvement amount data, data or an image of the improvement amount is registered.

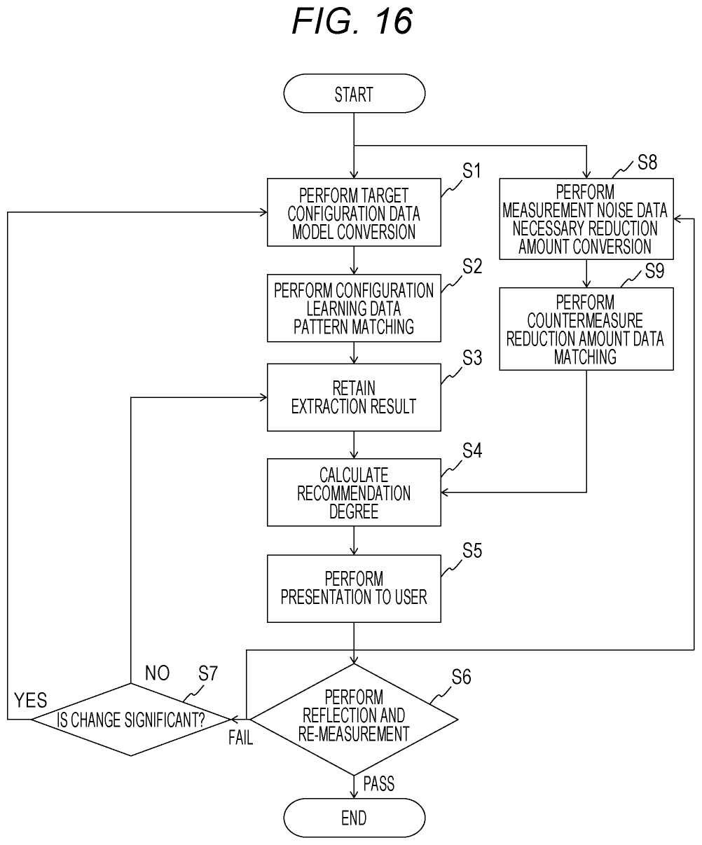

FIG. 16 is a flowchart illustrating an EMC countermeasure presentation method according to the present embodiment.

In the EMC countermeasure presentation system 1, when the processing is started, model conversion of target configuration data is performed in step S1.

Then, in step S2, pattern matching of the configuration learning data is performed.

Then, in step S3, the extraction result is retained.

In parallel with the processing of steps S1 to S3, in step S8, conversion of the necessary reduction amount of the measurement noise data is performed, and subsequently, in step S9, matching of the countermeasure reduction amount data is performed.

Then, in step S4, the recommendation degree is calculated based on the pattern matching result of the configuration learning data in step S2 and the matching result of the countermeasure reduction amount data in step S9.

Then, in step S5, the recommended countermeasure contents based on the recommendation degree obtained in step S4 are presented to the user.

Then, in step S6, a re-measurement result after the recommended countermeasure content is reflected is determined. In the case where the result is acceptable, the processing ends. In the case where the result is not acceptable, the process returns to step S8, the processing in and after step S8 is repeated, and it is determined in step S7 whether or not the change is significant.

In a case where it is determined in step S7 that the change is significant (Yes), the process returns to step S1, and the processing in and after step S1 is repeated. In a case where it is determined that the change is not significant (No), the process returns to step S3, and the processing in and after step S3 is repeated. In a case where the change is not significant enough to change the configuration, the processing time can be shortened by reusing the previous contents.

As described above, the EMC countermeasure presentation system 1 in the present embodiment includes the necessary reduction amount extraction unit 5 that converts measurement noise frequency data of the evaluation target device with the predetermined threshold value as the reference and generates necessary reduction amount frequency data, the reduction countermeasure extraction unit 2 that extracts the noise countermeasure reduction amount frequency data close in distance from the countermeasure reduction amount learning data obtained by learning the noise countermeasure reduction amount frequency data in the noise reduction countermeasure database (DB) 7 based on the necessary reduction amount frequency data generated by the necessary reduction amount extraction unit 5, the similar configuration extraction unit 3 that extracts device configuration data close in distance from configuration learning data obtained by learning a graph model representing a device configuration when the noise countermeasure reduction amount frequency data in the noise reduction countermeasure database (DB) 7 is acquired, based on the device configuration data at time of noise measurement of the evaluation target device, and the countermeasure estimation unit 4 that estimates a recommended countermeasure content having a high similarity in a device connection configuration and an expected effect of reducing excessive noise, from data obtained from the reduction countermeasure extraction unit 2 and the similar configuration extraction unit 3.

As a result, it is possible to also utilize the countermeasure contents in another device and another model, and it is possible to reduce the examination time and cost at the time of examining emission countermeasures.

In addition, by utilizing the electromagnetic connection graph data indicating the electromagnetic connection relationship, it is possible to eliminate the dependency of the description of the countermeasure content, and it is possible to quantitatively detect the countermeasure change influence degree and the like in the design system.

The present invention is not limited to the above embodiment, and various modification examples may be provided. For example, the above embodiment is described in detail in order to explain the present invention in an easy-to-understand manner, and the above embodiment is not necessarily limited to a case including all the described configurations. Further, some components in one embodiment can be replaced with the components in another embodiment, and the configuration of another embodiment can be added to the configuration of one embodiment. Regarding some components in the embodiments, other components can be added, deleted, and replaced.

What is claimed is:

1. An EMC countermeasure presentation system comprising:
a necessary reduction amount extraction unit that converts measurement noise frequency data of an evaluation target device with a predetermined threshold value as a reference and generates necessary reduction amount frequency data;
a reduction countermeasure extraction unit that extracts noise countermeasure reduction amount frequency data close in distance from countermeasure reduction amount learning data obtained by learning noise countermeasure reduction amount frequency data in a noise reduction countermeasure database based on the necessary reduction amount frequency data generated by the necessary reduction amount extraction unit;
a similar configuration extraction unit that extracts device configuration data close in distance from configuration learning data obtained by learning a graph model representing a device configuration when the noise countermeasure reduction amount frequency data in the noise reduction countermeasure database is acquired, based on the device configuration data at time of noise measurement of the evaluation target device; and
a countermeasure estimation unit that estimates a recommended countermeasure content having a high similarity in a device connection configuration and an expected effect of reducing excessive noise, from data obtained from the reduction countermeasure extraction unit and the similar configuration extraction unit.

2. The EMC countermeasure presentation system according to claim 1, further comprising:
a data commonization processing unit that converts time-series data and spectrogram data of the measurement noise frequency data in data registration processing of the noise reduction countermeasure database into two-dimensional frequency axis data.

3. The EMC countermeasure presentation system according to claim 1, wherein
the countermeasure estimation unit performs computation based on a graph convolution neural-network (GCN) that performs convolution integration of feature amounts on a connection model and expresses a result of the convolution integration as a feature amount of each component.

4. An EMC countermeasure presentation method comprising:
(a) converting measurement noise frequency data of an evaluation target device with a predetermined threshold value as a reference and generates necessary reduction amount frequency data;
(b) extracting noise countermeasure reduction amount frequency data close in distance from countermeasure reduction amount learning data obtained by learning noise countermeasure reduction amount frequency data in a noise reduction countermeasure database based on the necessary reduction amount frequency data generated in (a);
(c) extracting device configuration data close in distance from configuration learning data obtained by learning a graph model representing a device configuration when the noise countermeasure reduction amount frequency data in the noise reduction countermeasure database is acquired, based on the device configuration data at time of noise measurement of the evaluation target device; and
(d) estimating a recommended countermeasure content having a high similarity in a device connection configuration and an expected effect of reducing excessive noise, from data obtained from (b) and (c).

5. The EMC countermeasure presentation method according to claim 4, further comprising:
(e) converting time-series data and spectrogram data of the measurement noise frequency data in data registration processing of the noise countermeasure reduction amount frequency data into two-dimensional frequency axis data.

6. The EMC countermeasure presentation method according to claim 4, wherein
in (d), computation is performed based on a graph convolution neural-network (GCN) that performs convolution integration of feature amounts on a connection model and expresses a result of the convolution integration as a feature amount of each component.
